(19) United States
(12) Patent Application Publication
(10) Pub. No.: US 2026/0173571 A1
(43) Pub. Date: Jun. 18, 2026

(54) METHOD FOR PRODUCING A SOLAR CELL

(71) Applicant: HANWHA Q CELLS GMBH, Bitterfeld-Wolfen (DE)

(72) Inventors: Lukas KEGELMANN, Bitterfeld-Wolfen (DE); Michael SCHLEY, Bitterfeld-Wolfen (DE); Ralf NIEMANN, Bitterfeld-Wolfen (DE); Fabian FERTIG, Bitterfeld-Wolfen (DE); Sebastian BEHRENDS, Bitterfeld-Wolfen (DE)

(21) Appl. No.: 19/128,650

(22) PCT Filed: Nov. 8, 2023
(86) PCT No.: PCT/DE2023/100843

§ 371 Date: Oct. 10, 2025

(30) Foreign Application Priority Data
Nov. 9, 2022 (DE) 10 2022 129 636.9

(51) Int. Cl. H10F 71/00; H10F 10/19

(52) U.S. Cl. CPC H10F 71/137; H10F 10/19; H10F 71/128; H10F 71/134

(57) ABSTRACT

A method for producing a solar cell including a self-organizing monolayer, having the following steps: a) preconditioning a solar cell precursor in a preconditioning zone, and b) coating the preconditioned solar cell precursor with the self-organizing monolayer in a coating zone, wherein the solar cell precursor is transported through the preconditioning zone and the coating zone one after the other by means of a horizontal transport system while at least partly contacting said transport system on one face, thereby being preconditioned in the preconditioning zone and then coated in the coating zone on one face.

### RELATED APPLICATIONS

The present application is a National Phase entry of PCT Application No. PCT/DE2023/100843, filed Nov. 8, 2023, which claims priority to German Patent Application No. 10 2022 129 636.9, filed Nov. 9, 2022, the disclosures of which are hereby incorporated by reference in their entirety.

### FIELD OF THE INVENTION

The invention relates to a method for producing a solar cell. The solar cell may be a single-junction solar cell or a multi-junction solar cell, also referred to as a tandem solar cell. A tandem solar cell comprises two or more solar cells, which are also referred to as subcells and are stacked one above another. A distinction is made here between mechanically stacked tandem solar cells, in which the subcells are produced separately from one another, and monolithic tandem solar cells, in which all of the subcells are constructed on the same substrate.

### BACKGROUND OF THE INVENTION

There are known solar cells which comprise an SAM (self-assembled monolayer). The SAM, though, has to date been realizable only on the laboratory scale and at low throughput. There is a demand, however, to produce a solar cell having an SAM on the industrial scale.

### SUMMARY

It is an object of the invention to provide a method for producing a solar cell with which a solar cell having a self-assembled monolayer can be produced on the industrial scale.

In accordance with the invention, the object is achieved by a method having the features of claim 1. Advantageous developments and modifications are indicated in the dependent claims.

In the method, the solar cell precursor is transported through different zones of an installation by means of a horizontal transport system and is treated with one-sided treatment steps. The focus here is on the configuration of the SAM on the solar cell precursor, being part of the layer structure of the solar cell. The method is a strict single-side operation.

The invention relates to a method for producing a solar cell having a self-assembled monolayer, comprising the following steps
a) preconditioning a solar cell precursor in a preconditioning zone,
b) coating the preconditioned solar cell precursor with the self-assembled monolayer in a coating zone, wherein the solar cell precursor is transported successively through the preconditioning zone and the coating zone by means of a horizontal transport system with which it is in contact at least partly by one side, and in this process on one side is preconditioned in the preconditioning zone and subsequently coated in the coating zone.

The method of the invention enables the solar cell precursor to be coated with the SAM as a mass manufacturing process. The applied SAM is part of the structure of the solar cell produced. The method does not just allow a solar cell precursor to be coated; instead, a multiplicity of solar cell precursors can be transported successively and/or adjacently through the various zones of the installation and coated. By integrating a number of operating steps in the installation, the method simplifies the entire operational flow of coating the solar cell precursor with the SAM, with upstream and optionally downstream surface conditioning operations. The preconditioning here is essential to ensure effective chemical bonding of the SAM molecules on the surface, to be coated, of the solar cell precursor. The advantage of the method is easy scalability and the strict one-sided treatment of the solar cell precursor. As a result, levels of consumption, including of an SAM precursor, can be very low, and all method steps are integrated advantageously into the installation. The order of the operating steps can be adapted via the configuration of the installation. Consequently, it is also possible to omit or to add individual operating steps.

The method is used for producing a single-junction solar cell or a multi-junction solar cell. The single-junction solar cell is configured as an individual solar cell, whereas the multi-junction solar cells comprise multiple subcells. The method is preferably configured for producing a multiplicity of solar cells having a self-assembled monolayer, with the multiplicity of solar cell precursors being transported successively and/or adjacently through the preconditioning zone and subsequently through the coating zone by means of the horizontal transport system with which it is in contact at least partly by one side.

The installation configured for carrying out the method is preferably an in-line installation which contains the horizontal transport system. The zones are configured preferably as replaceable and/or modifiable installation modules, each having a function assigned thereto. The horizontal transport system is preferably configured in such a way as to transport a multiplicity of solar cell precursors successively and/or adjacently through the entire installation. Preferably, installation zones are configured which perform full-area treatment of the solar cell precursor on one side of the solar cell precursor. Treatment thereof is performed exclusively on one side.

In one preferred embodiment, step a) comprises precleaning of the solar cell precursor, in which the solar cell precursor is transported through a precleaning zone and is precleaned on one side. The precleaning preferably comprises one-sided washing of the solar cell precursor with ethanol. This results in effective preconditioning. Following the precleaning, the solar cell precursor is preferably dried, to remove cleaning solution from the precleaned solar cell precursor.

Alternatively or additionally preferably, step a) comprises pretreatment of the solar cell precursor, in which the solar cell precursor is transported through a pretreatment zone and pretreated on one side. The pretreatment preferably comprises exposing one side of the solar cell precursor to ozone, UV radiation, O₂ plasma and/or N₂ plasma. The pretreatment preferably comprises exposing one side of the solar cell precursor to ozone and/or UV radiation. This results in effective preconditioning.

In one preferred embodiment, the solar cell precursor is preconditioned in step a) by means of washing with ethanol, water or ethanol/water mixtures and of ozone pretreatment. This additionally results in effective preconditioning.

The solar cell precursor is treated on one side in the treatment zones, more particularly coated on one side in the coating zone. This does not exclude the fact that chemicals or operations may also reach the side of the solar cell precursor that is not to be treated, more particularly coated, unintentionally, for example by way of the transport rollers of the transport system.

In step b), the solar cell precursor is preferably coated over the full area on one side, on the side opposite to the side which is in contact with the transport system. Following the coating, the solar cell precursor is preferably dried, to remove a solvent of the coating material.

A coating material used in step b) for coating the solar cell precursor with the self-assembled monolayer is preferably selected from the group consisting of: 2PACz ([2-(9H-carbazol-9-yl)ethyl]phosphonic acid), MeO-2PACZ ([2-(3,6-dimethoxy-9H-carbazol-9-yl)ethyl]phosphonic acid), Me-4PACz ([4-(3,6-dimethyl-9H-carbazol-9-yl)butyl]phosphonic acid), Me-2PACz ([2-(3,6-dimethyl-9H-carbazol-9-yl)ethyl]phosphonic acid), Br-2PACz ([2-(3,6-dibromo-9H-carbazol-9-yl)ethyl]phosphonic acid). Preference is given to the use in step b) of 2PACz. In the solar cell, the self-assembled monolayer acts preferably as a hole conductor layer in a tandem solar cell.

In one preferred embodiment, following step b), a step c) is performed of thermally treating the solar cell precursor, coated with the self-assembled monolayer, in an annealing zone, wherein the solar cell precursor is transported through the annealing zone by means of the horizontal transport system, in contact with the transport system on one side, and is thermally treated. As a result, solvent used during the coating operation can be removed. In addition, following step b) or c), a step d) may be carried out of aftercleaning the solar cell precursor, coated with the self-assembled monolayer, in an aftercleaning zone, wherein the solar cell precursor is transported through the aftercleaning zone by means of the horizontal transport system, in contact with the transport system on one side, and in the process is aftercleaned on one side in the aftercleaning zone. The aftercleaning preferably comprises washing of the solar cell precursor. As a result, excess material used for coating the solar cell precursor is removed.

Step b) preferably comprises knife coating, slot die deposition and/or spray coating and/or drip coating. Step b) more preferably employs spraying and/or slot die systems and/or dripping bars in order to realize one-sided coating.

In one preferred embodiment, the horizontal transport system comprises a multiplicity of transport rollers, wherein the transport rollers rotate in a rotational direction, so that a solar cell precursor lying on said rollers is transported in a transport direction through the preconditioning zone, the coating zone and, where present, the annealing zone and, where present, the aftercleaning zone.

The solar cell to be produced is preferably a tandem solar cell.

In one preferred embodiment, the solar cell precursor comprises a lower subcell of the tandem solar cell, which bears a recombination layer which is preconditioned in step a) and coated in step b).

The lower subcell preferably comprises a silicon-based absorber. The recombination layer is configured preferably as a TCO (transparent conductive oxide) layer, more preferably as an ITO (indium tin oxide) layer.

The layer structure of the lower subcell of the tandem solar cell is preferably as follows, in the order indicated:
an electrically conductive layer,
an absorber such as a silicon substrate in the form of a p-type or n-type Cz-Si substrate,
a back-side passivation,
a back-side metallization, wherein the back-side metallization comprises local contacts through the back-side passivation with the absorber,
wherein the recombination layer to be coated by the method of the invention is arranged on the electrically conductive layer.

Deposited preferably on the self-assembled monolayer following step b), optionally c) or d) is a perovskite absorber, for example Cs_{0.05}(MA_{0.83}, FA_{0.17})_{0.95}Pb(I_{0.83}, Br_{0.17})₃.

The method preferably further comprises a loading step, in which the solar cell precursor is loaded onto the horizontal transport system. The loading step takes place before step a). The method preferably further comprises an unloading step, in which the solar cell precursor is unloaded from the horizontal transport system. The unloading step represents the last method step.

The method is preferably carried out in an installation which is configured in such a way that the transport system transports the solar cell precursor through the installation during the full performance of the method. The transport system preferably transports a multiplicity of solar cell precursors adjacently and/or successively through the installation.

Further advantages and characteristics of the method are explained with reference to preferred embodiments, which are described below. The figures, however, are not drawn to scale, but should instead be understood purely schematically and illustratively.

### BRIEF DESCRIPTION OF THE DRAWINGS

In the figures:

FIG. 1 shows a cross-sectional view of a tandem solar cell which can be produced by the method of the invention, and

FIG. 2 shows an installation in which the method of the invention is performed.

### DETAILED DESCRIPTION

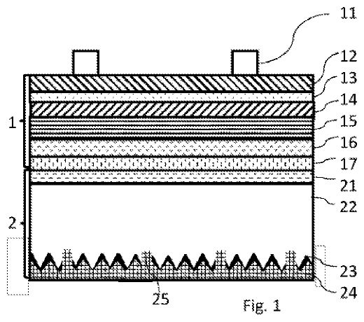

FIG. 1 shows a cross-sectional view of a tandem solar cell which can be produced by the method of the invention. It has the following structure in the order indicated:
a front-side metallization 11, comprising silver, for example,
an electrically conductive layer 12 such as an ITO layer,
a buffer and electron conductor layer 13 such as an SnO layer,
a passivated and hole blocking layer 14 such as a C60 layer,
an absorber 15, e.g., a perovskite absorber such as Cs_{0.05}(MA_{0.83}, FA_{0.17})_{0.95}Pb(I_{0.83}, Br_{0.17})₃,
a hole conductor layer 16, which represents the SAM or self-assembled monolayer, e.g., 2 PACz ([2-(9H-carbazol-9-yl)ethyl]phosphonic acid),
a recombination layer 17 such as an ITO layer,
a further electrically conductive layer 21,
a further absorber 22 such as a silicon substrate in the form of a p-type or n-type Cz-Si substrate,
a back-side passivation 23,
a back-side metallization 24, wherein the back-side metallization 24 comprises local contacts 25 through the back-side passivation 23 with the further absorber 22.

The tandem solar cell comprises an upper subcell 1 with the layers 11 to 17 and a lower subcell 2 with the layers 22 to 25. The subcell 1 comprises the perovskite-based absorber 15, while the subcell 2 comprises the silicon-based absorber 22.

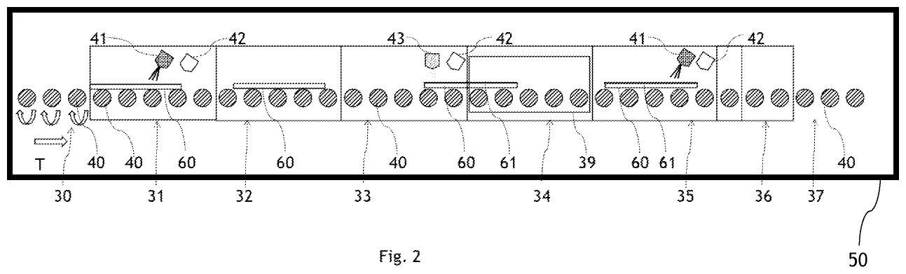

FIG. 2 shows an installation in which the method of the invention is performed. For carrying out the method, the installation comprises a plurality of zones which are designed for treating a solar cell precursor 60, respectively, and a horizontal transport system with transport rollers 40 which is arranged and configured in such a way as to transport the solar cell precursor 60 horizontally on one side through the zones. A plurality of solar cell precursors are shown, which are transported through the various zones of the installation. The installation comprises a loading zone 30, in which the transport system is loaded with the solar cell precursor 60, so that said precursor is in contact with the transport system by one side. Following the loading zone 30 is a preconditioning zone. The preconditioning zone comprises a precleaning zone 31, in which the solar cell precursor 60 is first precleaned on one side by means of a cleaning apparatus 41, with ethanol, for example, washed, and then dried by means of a drying apparatus 42, and/or comprises a pretreatment zone 32, in which the solar cell precursor 60 is pretreated on one side using ozone, for example.

Following the pretreatment zone 32 is a coating zone 33, in which the pretreated solar cell precursor 60 having a self-assembled monolayer 61 is coated on one side by means of a coating apparatus 43 and is optionally dried by means of a further drying device 42. Following the coating zone 33 is an optional annealing zone 34, in which the solar cell precursor 60 coated with the self-assembled monolayer 61 is thermally treated in a heat zone 39. The optional annealing zone 34 is followed by an optional aftercleaning zone 35, in which the solar cell precursor 60 coated with the self-assembled monolayer 61 is aftercleaned using a cleaning apparatus 41 and dried of a further drying apparatus 42. The optional aftercleaning zone 35 is followed by an optional drying zone 36, in which the solar cell precursor 60 coated with the self-assembled monolayer 61 is dried. The optional drying zone 36 is followed by an unloading zone 37, in which the solar cell precursor 60 coated with the self-assembled monolayer 61 is unloaded from the transport system.

The installation can be used to carry out the method of the invention for producing a solar cell 60 having a self-assembled monolayer 61, said method comprising the following steps:
a step a) of preconditioning a solar cell precursor 60 in the preconditioning zone, i.e., in the precleaning zone 31 and/or the pretreatment zone 32, and a step b) of coating the preconditioned solar cell precursor 60 with a self-assembled monolayer 61 in the coating zone 33, wherein the solar cell precursor 60 is transported successively through the preconditioning zone and the coating zone 33 by means of the horizontal transport system with which it is in contact at least partly by one side, and in this process, on the side facing away from the transport system, is preconditioned on one side in the preconditioning zone and subsequently coated on one side in the coating zone 33. Subsequently, the solar cell precursor 60 coated with the self-assembled monolayer 61 may be thermally treated and/or aftercleaned. In this way, for example, the hole conductor layer 16 of the tandem solar cell shown in FIG. 1 can be produced.

### LIST OF REFERENCE SIGNS

T transport direction
1 upper part-cell
11 front-side metallization
12 electrically conductive layer
13 buffer layer
14 electron conductor layer
15 absorber
16 hole conductor layer
17 recombination layer
2 lower part-cell
21 further electrically conducting layer
22 further absorber
23 back-side passivation
24 back-side metallization
25 local contact
3 installation
30 loading zone
31 precleaning zone
32 pretreatment zone
33 coating zone
34 annealing zone
35 aftercleaning zone
36 drying zone
37 unloading zone
39 heat zone
40 transport rollers
41 cleaning apparatus
42 drying apparatus
43 coating apparatus
60 solar cell precursor
61 self-assembled monolayer

1. A method for producing a solar cell having a self-assembled monolayer, comprising the following steps:
a) preconditioning a solar cell precursor in a preconditioning zone,
b) coating the preconditioned solar cell precursor with the self-assembled monolayer in a coating zone,
wherein the solar cell precursor is transported successively through the preconditioning zone and the coating zone by a horizontal transport system with which it is in contact at least partly by one side, and in this process on one side is preconditioned in the preconditioning zone and subsequently coated in the coating zone.

2. The method as claimed in claim 1, wherein step a) comprises precleaning of the solar cell precursor, in which the solar cell precursor is transported through a precleaning zone and is precleaned on one side, and/or comprises pretreatment of the solar cell precursor, in which the solar cell precursor is transported through a pretreatment zone and is pretreated on one side.

3. The method as claimed in claim 2, wherein the precleaning comprises washing one side of the solar cell precursor with ethanol and/or the pretreatment comprises exposing one side of the solar cell precursor to ozone, ultraviolet (UV) radiation, O₂ plasma and/or N₂ plasma.

4. The method as claimed in claim 1, wherein following step b), a step c) of thermally treating the solar cell precursor, coated with the self-assembled monolayer, is carried out in an annealing zone, wherein the solar cell precursor is transported through the annealing zone by the horizontal transport system, in contact with the transport system on one side, and is thermally treated.

5. The method as claimed in claim 1, wherein a step d) of after-cleaning the solar cell precursor, coated with the self-assembled monolayer, is carried out in an after-cleaning zone, wherein the solar cell precursor is transported through the after-cleaning zone by the horizontal transport system, in contact with the transport system on one side, and in the process is after-cleaned on one side in the after-cleaning zone.

6. The method as claimed in claim 1, wherein the solar cell precursor is treated on its side facing away from the transport system.

7. The method as claimed in claim 1, wherein step b) comprises knife coating, slot die deposition and/or spray coating and/or drip coating.

8. The method as claimed in claim 1, wherein the horizontal transport system comprises a multiplicity of transport rollers, wherein the transport rollers rotate in a rotational direction, so that a solar cell precursor lying on said rollers is transported in a transport direction through the preconditioning zone, the coating zone and, where present, an annealing zone and, where present, an after-cleaning zone.

9. The method as claimed in claim 1, wherein the solar cell precursor comprises a lower subcell of the solar cell, which is to be produced as a tandem solar cell and bears a recombination layer which is preconditioned in step a) and coated in step b), wherein the lower subcell comprises a silicon-based absorber and/or the recombination layer is configured as a TCO layer.

10. The method as claimed in claim 1, wherein the method is carried out in an installation which is configured in such a way that the transport system transports the solar cell precursor through the installation during the complete performance of the method.

11. The method as claimed in claim 1, wherein the solar cell precursor comprises a lower subcell of the solar cell, which is to be produced as a tandem solar cell and bears a recombination layer which is preconditioned in step a) and coated in step b), wherein the lower subcell comprises a silicon-based absorber and/or the recombination layer is configured as an ITO layer.
